(19) United States
(12) Patent Application Publication
(10) Pub. No.: US 2009/0038674 A1
(43) Pub. Date: Feb. 12, 2009

(54) Photovoltaic Module

(76) Inventor: Lothar Bieber, Buschow (DE)

Correspondence Address: Law Offices of Karl Hormann, P.O. Box 381516, Cambridge, MA, 02238-1516, US

(21) Appl. No.: 11/975,947

(22) Filed: Oct. 22, 2007

(30) Foreign Application Priority Data
Oct. 21, 2006 (DE) DE 102006049790.2
Jun. 13, 2007 (DE) DE 102007027207.5

(51) Int. Cl. H01L 31/042

(52) U.S. Cl. 136/251; 136/244

(57) ABSTRACT

A photovoltaic module with photocells mounted between two superposed and adhesively connected panes of toughened safety glass (ESG-glass) and a web of suitable material with grooves in a surface placed over and adhesively connected to one of the panes to form channels for the flow of cooling liquid.

### BACKGROUND OF THE INVENTION

1. Field of the Invention

The invention, in general, relates to a photovoltaic module of the kind useful for the conversion of light to electric current and, more particularly, to a photovoltaic module provided with means for cooling solar cells.

2. The Prior Art

It is generally known that the effectiveness of solar cells is substantially reduced by strong heat since the electric conductivity of a semiconductor, usually silicon, is to a significant extent a function of temperature. Depending upon temperature, a semiconductor may be considered a conductor or non-conductor. At temperatures below 0° C. it is not usually conductive. The electric conductivity of a semiconductor increases with increasing temperature which leads to a significant reduction, e.g. 80% of its overall output, in its effectiveness.

Proposals aiming at improving the effectiveness of photovoltaic systems have not been lacking. For instance, DE 197 47 325 A1 describes a solar cell module with integrated cooling of the solar cells. With a view to increasing the effectiveness of the solar cell on hot days, the cells are mounted on a metal container of good thermal conductivity which is filled with a liquid coolant. The purpose of the container is to transfer heat generated at the photovoltaic module to the liquid by means of vanes. However, the described system appears to suffer from the drawback that its structure prevents universal use of the system. This is true also of its controllability, for precipitated snow will stay on the module thereby rendering it non-functioning. Another disadvantage is that in desert regions little water would be available for filling the container and that ventilation problems arise.

DE 202 14 078 U1 discloses a photovoltaic system using an extruded transparent channel of polymer material in which photovoltaic cells connected in a strand are floating in a cooling medium in order omnidirectional to disperse its heat into the cooling medium in the channel. Disregarding the fact that the proposed system requires the use of optical elements such as Fresnel lenses, linear lenses or focusing lenses to concentrate impinging light onto the floating cells when renders its use under harsh natural conditions extremely problematic, it requires a special and likely expensive dielectric cooling liquid of high light permeability which would appear to render the system uneconomical. Moreover, chemical cooling liquids very likely affect the individual components in a negative way.

A solar cell has been described in DE 10 2004 002 900 A1 in which an aluminum frame provided with an unbreakable and antireflectively coated pane and a waterproof rubber gasket is deposited on a photovoltaic module. The aluminum frame is provided with many differently sized nozzles to allow water or another coolant uniformly to flow through and leave the narrow intermediate without allegedly building up pressure. Nevertheless the pane is may break in consequence of excessive coolant pressure in view of the fact that the force of the pressure acting on the pane increases proportionally to increases in coolant pressure and the size of the pane, i.e. the force of pressure exerted on the pane increases with the surface to be cooled and thus raises the likelihood of breakage of the pane and/or module. While this may be avoided by a pane of increased thickness or quality, the fact remains that where the cooling system is mounted over or in front of the module the intensity of light impinging on the module is reduced substantially as is the effectiveness of the module, particularly if the coolant, over time, becomes opaque.

Similar disadvantages would be encountered in connection with apparatus of the kind disclosed by DE 199 23 196 A1 which proposes the use of a recuperative selective liquid filter for photovoltaic modules. In this case a front surface subjected to impinging radiation and an opposite rear surface serve to convert radiation energy into electric current. The cooling device is arranged between the source of radiation and the front surface. The increased weight of the entire system limits its mountability and because of the low temperature the use of a cooling medium renders it ineffective for domestic purposes.

For increasing the yield of energy by cooling the photovoltaic module as proposed by DE 101 21 850 A1, cooling liquid is conducted through an intermediate chamber at the rear surface of a commercial module. The intermediate chamber is formed by a pane of glass adhesively attached by silicon. However, the foil attached is not completely diffusion-proof so that the cooling medium may penetrate to, and short-circuit, the silicon cells. The silicon used as an adhesive, when contacting the PVB foil, initiates a negative reaction which may lead to irreparable damage.

### OBJECTS OF THE INVENTION

It is a primary object of the instant invention to provide a cooled photovoltaic module which avoids the disadvantages of cooled prior art modules.

Another object of the invention is to provide a cooled photoelectric modules which retains its initial effectiveness over time.

Yet another object resides in the provision of a cooled photoelectric module which can be fabricate easily.

Still another object is to provide a photovoltaic module of the kind referred to which can be economically manufactured.

It is also an object of the invention to provide a cooled photovoltaic module which can be serviced without any complexity.

These and other objects will in part be obvious and will in part appear hereinafter.

### BRIEF SUMMARY OF THE INVENTION

In the accomplishment of the objects referred to the invention provides for a cooled photovoltaic module

### DESCRIPTION OF THE SEVERAL DRAWINGS

The novel features which are deemed to be characteristic of the invention are set forth with particularity in the appended claims. The invention itself, however, in respect of its structure, construction, lay-out and design, as well as manufacturing techniques and technology, together with other objects and advantages thereof will be best understood from the following description of the preferred embodiments when read with reference to the appended drawings, in which:

FIG. 1 is a side sectional view of a photovoltaic module in accordance with the invention in an upright disposition; and

FIG. 2 is a cross-sectional view of the photocell in accordance with the invention in a horizontal disposition.

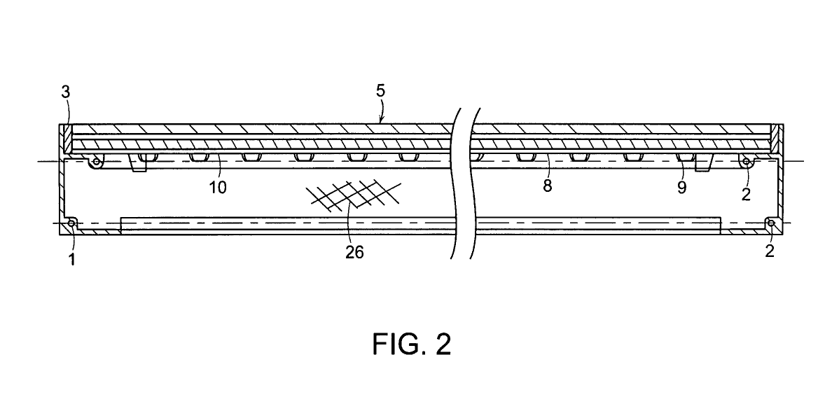

### DETAILED DESCRIPTION OF THE PREFERRED EMBODIMENT

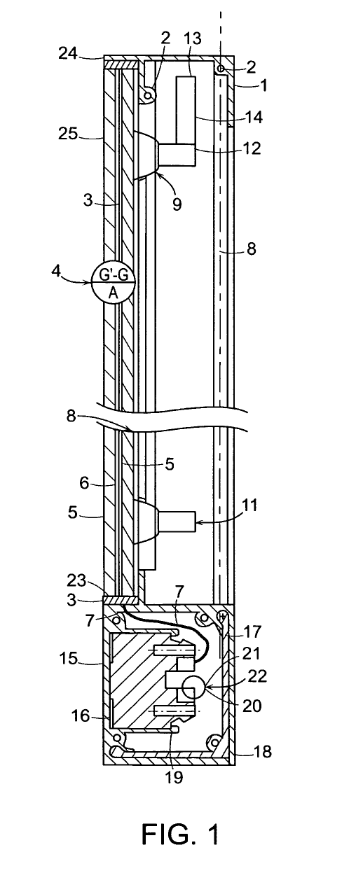

As may be seen in FIG. 1, all the necessary components of the photovoltaic module are housed within a special frame 1 which may be made, for instance, of aluminum and which is provided with screw channels 2 for a threaded connection and tightening the corners. A special glass/glass module 4 is used for the solar unit mounted as a surface into the frame 1 by a UV-resistant two-component adhesive. The size of the module depends upon the size of the type of cell. The module is made up of two superposed panes 5 of toughened safety glass (ESG glass) with a foil 6 placed between them, silicon cells and current conductors 7 for conducting current at the front surface as well as at the rear surface.

The cooling device is adhesively attached to the rear surface of the glass/glass module 4 by a UV-resistant two-component adhesive 3 and consists of a web 8 of corrosion-resistant sheet metal or polymer structured to accommodate the absorption of heat. Grooves 9 of substantially U-shaped cross-section penetrate deeply into the web 8 and extend or meander laterally and vertically in the surface thereof and are disposed so that between them, i.e. between their openings, they form a sturdy support and adhesive surface 10 facing the glass pane 5. The grooves may be formed in the web by any of the well-known methods, embossing, engraving, cutting, routing and casting being mentioned by way of example. A UV-resistant two-component adhesive is suitable for this purpose as well. The process makes it possible adhesively to connect large glass panes 4 to sheet metal or polymer webs 8 and results in the formation of a large surface area with many small channels which optimally distribute water pressure when exposed to heat.

The grooves 9 in the web 8 are connected to a liquid coolant circulation system (not shown) by at least one input connector 11 and one output connector 12. Ventilation may be provided either by a ventilation valve 13 at the highest point of the cooling device or outside of the photovoltaic module at an output flow conduit 14 of the output connector 12.

The apparatus of the instant invention differs from known solar modules with electrical connectors integrated in the module and inaccessible during operation not least by an electrical connector rail 15 extending within the frame 1 over the entire width of the photovoltaic module for connecting individual modules as well as for receiving a module outlet 16 which may be threadedly connected at the left, right or on top of the module. The electric connector rail 15 is made of a UV-resistant polymer with integrated extrusion-molded sealing lips 17. A lid 18 is may either be snapped on or threadedly connected with the electric connector rail 15. The electric connector rail 15, by its special arrangement, thus makes possible cross-over connections outside of the glass/glass module 4. This is true as well for the accessibility of the current tapes 7 outside of the glass/glass module 4. Clip-hooks 19 provide a secure connection between the module outlet 16 and connector blades 20 which may be moved along the entire length of the rail. The connection blades between modules are also covered by the electric connector rail 15. Necessary diodes 21 are structured such that they may be provided with cooling vane clips 22 made of extruded aluminum to avoid overheating of the diodes 21. The electric connector rail 15 in connection with the aluminum frame 1 provides a frame surrounding the cooling device. With the electric connector rail 15 forming one side of the frame, the remaining three side thereof are formed by the aluminum frame. The resultant compact and prefabricated unit of glass/glass module 4 and cooling unit are adhesively connected to the frame, with a small space 23 to allow for different expansion coefficients of different materials, by a two-component adhesive.

The upper edge 24 of the frame 1 and the surface 25 of the glass 4 form a planar surface without any protrusion. The formation of moss or mildew as a result of penetrating humidity, or frost damage as a result of ice and snow, are prevented as well. If the apparatus in accordance with the invention is used in desert regions, a movable insulation 26 may be provided at the rear surface of the cooling device and is opened at night by thermal cylinders so that as a result of lower night-time temperatures the cooling liquid is more rapidly cooled in a buffer storage. During daytime the insulation will automatically engage the rear surface of the cooling device and protect the entire photovoltaic module from high outside temperatures.

What is claimed is:

1. A photovoltaic module, comprising:
first and second superposed panes of glass connected to each other by an adhesive;
a web of one of sheet metal and polymeric material provided with at least one groove penetrating into a surface thereof and connected to one of the panes with the groove facing the pane to form a conduit by an adhesive; and
means for connecting the conduit to a source of coolant.

2. The module of claim 1, wherein the adhesive is a UV-resistant two-component adhesive.

3. The module of claim 1, wherein the grooves are of substantially U-shaped cross-section.

4. The module of claim 1, wherein the means for connecting the conduit to a source of coolant comprises an input connector and an output connector.

5. The module of claim 1, wherein the glass comprises a toughened safety glass (ESG glass).

6. The module of claim 4, further comprising ventilation means at one of the highest point of the module and the output connector.

7. The module of claim 1, further comprising a frame surrounding the panes of glass and the web at at least three sides thereof.

8. The module of claim 7, further comprising an electric connector rail at a fourth side of the panes and web.

9. The module of claim 7, wherein the frame is made of aluminum.

10. The module of claim 8, wherein the frame is provided with threaded recess.
